(19) United States
(12) Patent Application Publication
(10) Pub. No.: US 2014/0333911 A1
(43) Pub. Date: Nov. 13, 2014

(54) LITI MASK AND LASER IRRADIATION DEVICE INCLUDING THE SAME

(71) Applicant: SAMSUNG DISPLAY CO., LTD., YONGIN-CITY (KR)

(72) Inventor: TAE MIN KANG, Suwon-si (KR)

(73) Assignee: SAMSUNG DISPLAY CO., LTD., YONGIN-CITY (KR)

(21) Appl. No.: 14/060,156

(22) Filed: Oct. 22, 2013

(30) Foreign Application Priority Data
May 10, 2013 (KR) 10-2013-0053347

(51) Int. Cl. G03F 7/20; G03F 1/22

(52) U.S. Cl. CPC G03F 7/2006; G03F 1/22
USPC 355/67; 430/5

(57) ABSTRACT

A laser irradiation device includes a light source, a laser induced thermal imaging (LITI) mask, and a stage. The light source may emit a laser beam at constant output energy. The LITI mask may be disposed under the light source. The stage may be disposed under the LITI mask, and an acceptor substrate including a pixel area is disposed on the stage. The LITI mask may include a transmissive part and a blocking part. The transmissive part has a plurality of slits. The laser beam passes through the slits. The transmissive part corresponds to the pixel area. The blocking part may reflect and block the laser beam.

### CROSS-REFERENCE TO RELATED APPLICATIONS

This U.S. non-provisional patent application claims priority under 35 U.S.C. §119 of Korean Patent Application No. 10-2013-0053347, filed on May 10, 2013, the disclosure of which is incorporated by reference herein in its entirety.

### TECHNICAL FIELD

Exemplary embodiments of the present disclosure herein relate to manufacturing organic light emitting devices, and more specifically, to a laser induced thermal imaging (LITI) mask and a laser irradiation device including the same.

### DISCUSSION OF RELATED ART

An organic light emitting device may include, in addition to an organic emitting layer, at least one organic layer. The organic layer may be patterned by a laser induced thermal imaging (LITI) method. During the patterning process of the organic layer using the LITI method, cracks may occur in the organic layer due to a sudden expansion of a donor substrate.

### SUMMARY

A laser induced thermal imaging (LITI) mask according to an exemplary embodiment of the inventive concept forms an organic layer on a pixel area. The LITI mask may include a transmissive part and a blocking part. The transmissive part may correspond to the pixel area. The transmissive part may have a plurality of slits. A laser beam passes through the plurality of slits. The blocking part may reflect and block the laser beam.

Each of the slits may extend in a direction substantially perpendicular to a scanning direction of the laser beam. The slits may be spaced apart from each other in the scanning direction. Each of the slits may have a width in the scanning direction. The width is substantially equal to a distance between two slits adjacent to in the scanning direction.

A laser irradiation device according to an exemplary embodiment of the inventive concept may include a light source, a (laser induced thermal imaging (LITI) mask, and a stage. The light source may emit a laser beam at constant output energy. The LITI mask may be disposed under the light source. The stage may be disposed under the LITI mask. An acceptor substrate having a pixel area may be disposed on the stage.

As the stage moves in a scanning direction of the laser beam, the laser beam may have a square wave form.

A laser irradiation device according to an exemplary embodiment of the inventive concept may include a light source, a (laser induced thermal imaging (LITI) mask, and a stage. The light source may emit a laser beam. The laser beam alternately has at least two energy values different from each other. The laser beam may have a square wave form.

The LITI mask may include a transmissive part and a blocking part. The transmissive part may correspond to a pixel area. The transmissive part includes an opening through which the laser beam passes. The opening has a dot shape. The blocking part may reflect and block the laser beam.

According to an exemplary embodiment of the inventive concept, a laser irradiation device includes a light source emitting a laser beam. A laser induced thermal imaging (LITI) mask is disposed under the light source. A stage is disposed under the LITI mask. An accepter substrate having a pixel area is disposed on the stage. The LITI mask comprises a transmissive part through which the laser beam passes. The transmissive part corresponds to the pixel area. The LITI mask includes a blocking part. After passing through the transmissive part, the laser beam has a square wave form. The transmissive part may include a plurality of slits. The transmissive part may include an opening. The laser beam may have at least two energy values that vary over time. The opening may be rectangular in shape.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a perspective view illustrating a laser irradiation device according to an exemplary embodiment of the inventive concept;

FIG. 2 is a plan view illustrating a transmissive part and a blocking part adjacent to the transmissive part in a laser induced thermal imaging (LITI) mask of FIG. 1, according to an exemplary embodiment of the inventive concept;

FIG. 3A is a graph illustrating output energy of a laser beam over time before passing through an LITI mask according to an exemplary embodiment of the inventive concept;

FIG. 3B is a graph illustrating output energy of a laser beam over time after passing through an LITI mask of FIG. 1, according to an exemplary embodiment of the inventive concept;

FIG. 4 is a photograph of a green pixel formed using a typical a laser irradiation device according to an exemplary embodiment of the inventive concept;

FIG. 5 is a photograph of a green pixel formed using a laser irradiation device according to an exemplary embodiment of the inventive concept;

FIG. 6 is a plan view illustrating a transmissive part and a blocking part adjacent to the transmissive part in an LITI mask according to an exemplary embodiment of the inventive concept; and

FIG. 7 is a graph illustrating output energy of a laser beam over time before passing through an LITI mask according to an exemplary embodiment of the inventive concept.

### DETAILED DESCRIPTION OF THE EMBODIMENTS

Hereinafter, exemplary embodiments of the inventive concept will be described in detail with the accompanying drawings. The inventive concept may, however, be embodied in different forms and should not be construed as limited to the embodiments set forth herein. The same numerals may denote the same or substantially the same elements throughout the specification and the drawings.

As used herein, the singular forms “a,” “an,” and “the” are intended to include the plural forms as well, unless the context clearly indicates otherwise.

It will be understood that when an element or layer is referred to as being “on,” “connected to,” “coupled to,” or “adjacent to” another element or layer, it can be directly on, connected, coupled, or adjacent to the other element or layer, or intervening elements or layers may be present.

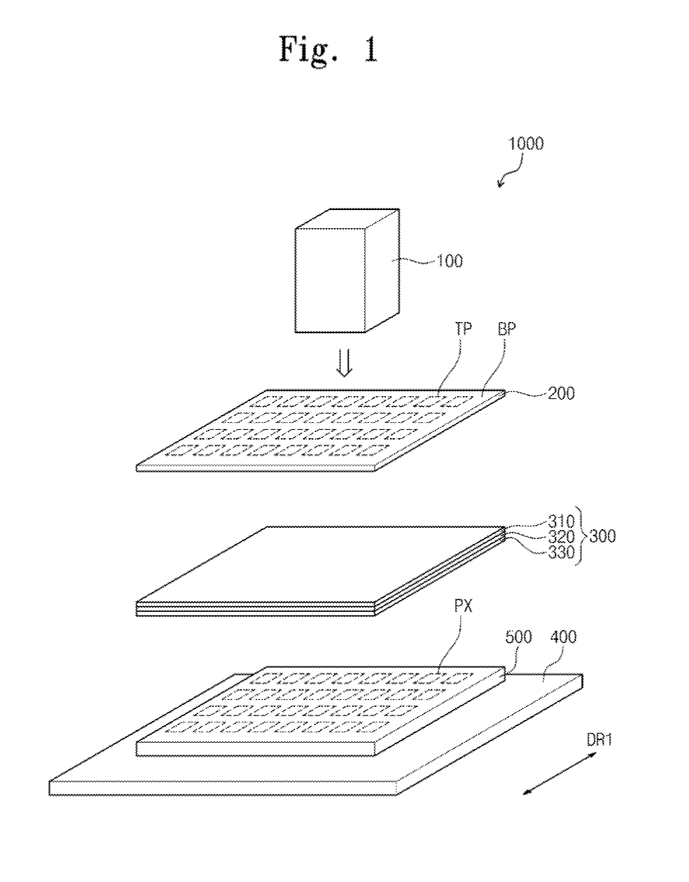

FIG. 1 is a perspective view illustrating a laser irradiation device 1000 according to an exemplary embodiment of the inventive concept.

The laser irradiation device 1000 may include a light source 100, a laser induced thermal imaging (LITI) mask 200, and a stage 400.

The light source 100 emits a laser beam at constant output energy. The laser beam passes through a plurality of slits OP1 of the LITI mask 200 to a donor substrate 300. The light source 100 may include a gas laser, such as an argon (Ar) laser, a krypton (Kr) laser, and an excimer laser, a laser using a medium with monocrystalline terbium aluminum garnet (TAG), YVO₄, Mg₂SiO₄, YAlO₃, and GdVO₄, or polycrystalline (ceramic) yttrium aluminum garnet (YAG), Y₂O₃, YVO₄, YAl₃, or GdVO₄ doped with neodymium (Nd), ytterbium (Yb), chrome (Cr), titanium (Ti), holmium (Ho), Erbium (Er), thulium (Tm), and/or tantalum (Ta), a glass laser, a ruby laser, an alexandrite laser, a Ti: sapphire laser, a copper vapor laser, and/or a gold vapor laser. The laser beam may have a rectangular or linear shape in which the beam may be more easily focused rather as compared with when the laser beam has a surface shape in which the beam is dispersed over an entire surface of a substrate.

The LITI mask 200 is disposed between the light source 100 and the stage 400. The LITI mask 200 is a light control unit for selectively blocking or reflecting the laser beam emitted from the light source 100.

The LITI mask 200 may include a transmissive part TP and a blocking part BP. The transmissive part TP corresponds to a pixel area PX defined on an acceptor substrate 500. A portion of the laser beam incident to the transmissive part TP may pass through the LITI mask 200. The blocking part BP is an area except the transmissive part TP, and the blocking part BP reflects or blocks the laser beam.

The LITI mask 200 may be formed of a material that may resist the laser beam. For example, the LITI mask 200 may be formed of a metal that has a low thermal expansion rate and a high melting point, such as, e.g., tungsten, tantalum, chrome, nickel, and molybdenum, or an alloy thereof, stainless steel, inconel, or hastelloy.

The acceptor substrate 500 may be placed on the stage 400. As the laser beam is radiated from the light source 100, the stage 400 may move in a scanning direction DR1.

The acceptor substrate 500 includes a plurality of pixel areas PX. The pixels areas PX are formed on a layer formed of an insulating material. An anode electrode is formed on each pixel area PX. An organic layer including RGB organic emitting layers is formed on the anode electrode by the donor substrate 300. A cathode electrode is formed on the organic layer. A thin film transistor TFT electrically connected to the anode electrode as a driving element is formed on the acceptor substrate 500.

The donor substrate 300 may be disposed between the LITI mask 200 and the acceptor substrate 500. The donor substrate 300 may be laminated on the acceptor substrate 500. The donor substrate 300 may include a base film 310, a light-to-heat conversion (LTHC) layer 320, and a transfer layer 330. The laser beam emitted from the light source 100 is absorbed into the LTHC layer 320 and is then converted into heat energy. The converted heat energy may change an adhesion force between the LTHC layer 320, the transfer layer 330, and the acceptor substrate 500. Accordingly, the transfer layer 330 is transferred onto the acceptor substrate 500, forming the organic layer on the acceptor substrate 500. For example, the transfer layer 330 is detached from the LTHC layer 320, and thus, the transfer layer 330 is transferred onto the acceptor substrate 500, forming the organic layer on the acceptor substrate 500.

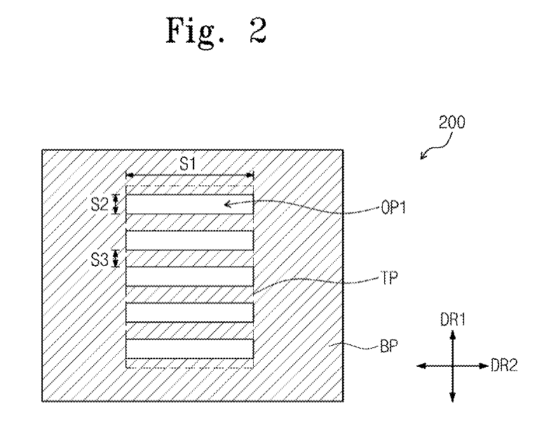

FIG. 2 is a plan view illustrating a transmissive part and a blocking part adjacent to the transmissive part in an LITI mask of FIG. 1, according to an exemplary embodiment of the inventive concept.

Referring to FIGS. 1 and 2, a plurality of slits OP1 is formed in the transmissive part TP. Each of the slits OP1 extends in a direction DR2 substantially perpendicular to the scanning direction DR1.

The slits may be spaced apart from each other in the scanning direction DR1. A remaining portion of the transmissive part TP except for the slits OP1 may be formed of substantially the same material as the blocking part BP.

Each of the slits has a size varying according to the resolution of a display panel.

Each slit may have a length S1 in the direction DR2 and a width S2 in the scanning direction DR1. The length Si is larger than the width S2. The width S2 may be in a range from about 10 μm to about 100 μm. The distance S3 between slits adjacent to each other may be in a range from about 10 μm to about 100 μm.

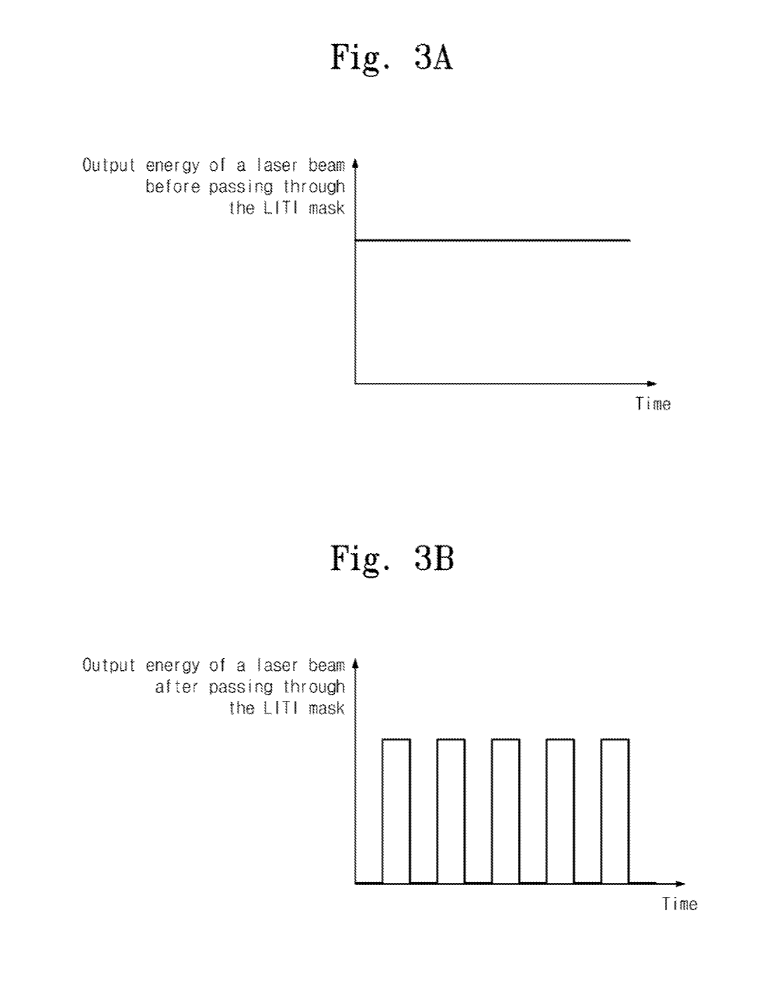

FIG. 3A is a graph illustrating output energy of a laser beam over time before passing through an LITI mask according to an exemplary embodiment of the inventive concept. FIG. 3B is a graph illustrating output energy of a laser beam over time after passing through an LITI mask of FIG. 1, according to an exemplary embodiment of the inventive concept.

Referring to FIGS. 1, 2, and 3A, the laser beam emitted from the light source 100 has constant output energy over time. The laser beam has constant output energy before the laser beam passes through the LITI mask 200.

Referring to FIGS. 1, 2, and 3B, the laser beam provided onto the LITI mask 200 passes through the slits OP1 having the plurality of slits, but not the blocking part BP and the remaining portion of the transmissive part TP except for the slits OP1.

The donor substrate 300 and the acceptor substrate 500 are laminated on the stage 400. When the stage 400 moves in the scanning direction DR1, the laser beam passing through the LITI mask 200 to the donor substrate 300 may have a square wave form. Thus, the constant output energy of the laser beam is continuously provided onto the donor substrate 300, thus preventing sudden expansion of the donor substrate 300.

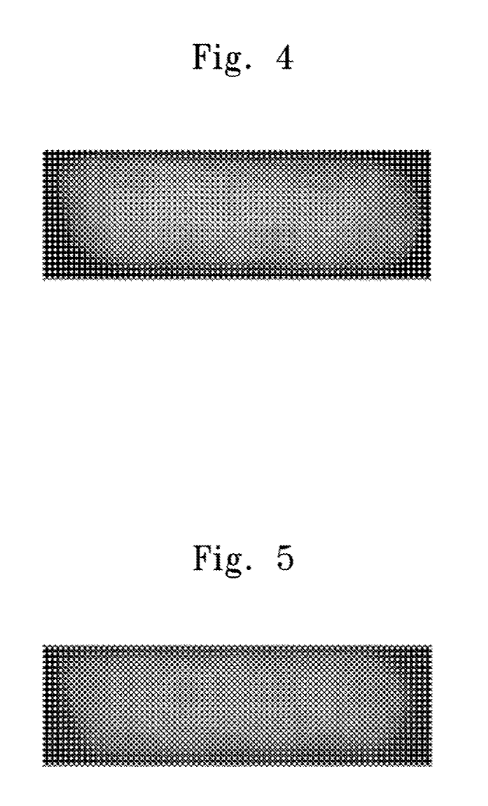

FIG. 4 is a photograph of a green pixel formed using a conventional laser irradiation device. FIG. 5 is a photograph of a green pixel formed using a laser irradiation device according to an exemplary embodiment of the inventive concept.

Referring to FIG. 4, in the conventional laser irradiation device, a laser beam is emitted at constant output energy from a light source, and an LITI mask includes an opening having a dot shape that corresponds to a pixel area. The laser beam that is emitted from the light source and passes through the opening of the LITI mask to a donor substrate has constant output energy over time. Since the laser beam energy is continuously concentrated onto the donor substrate, the donor substrate may be suddenly expanded. When a transfer layer is transferred onto an acceptor substrate to form an organic layer, the organic layer may have cracks due to the thermal expansion of the donor substrate. Referring to FIG. 4, black lines are shown in the green pixel due to the cracks of the organic layer.

Referring to FIG. 5, in the laser irradiation device according to an exemplary embodiment of the inventive concept, since the laser beam passing through an LITI mask has a square wave form as shown in FIG. 3B due to the slits OP1 in the LITI mask, a sudden expansion of the donor substrate may be prevented. No cracks are created in the organic layer, and thus, no black lines are shown in FIG. 5.

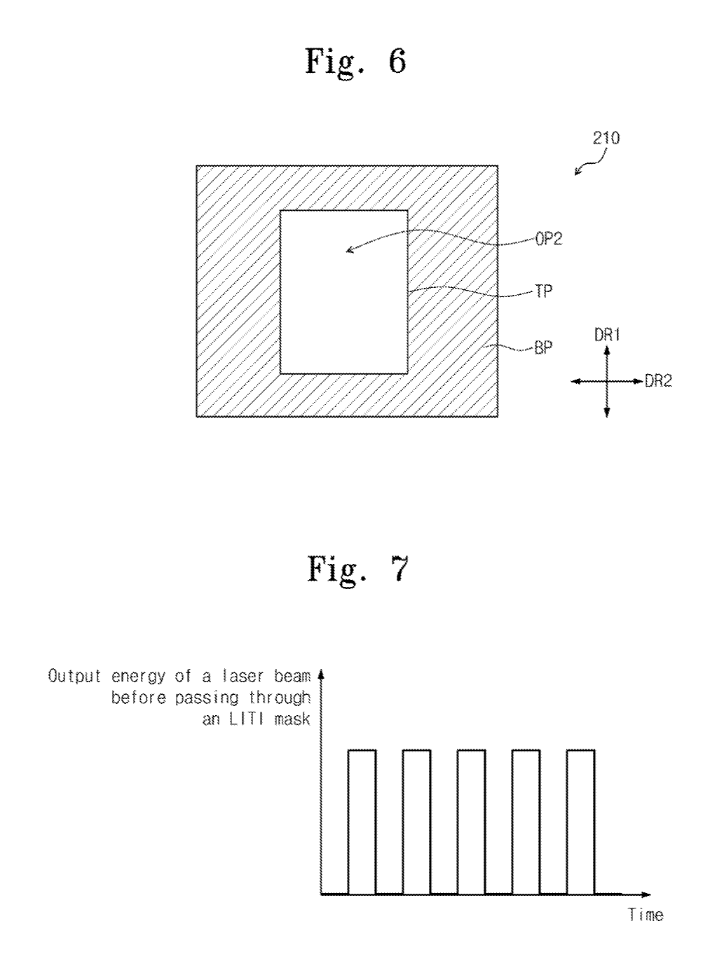

FIG. 6 is a plan view illustrating a transmissive part TP and a blocking part BP adjacent to the transmissive part TP in an LITI mask 210 according to an exemplary embodiment of the inventive concept.

Referring to FIG. 6, the transmissive part TP corresponds to a pixel area defined on an acceptor substrate 500. An opening OP2 having a dot shape is defined in the transmissive part TP. For example, the transmissive part TP includes one opening OP2. Thus, all of the laser beams incident into the transmissive part TP may pass through the LITI mask 210.

FIG. 7 is a graph illustrating output energy of a laser beam over time before passing through an LITI mask according to an exemplary embodiment of the inventive concept.

Referring to FIGS. 1 and 7, the light source 100 emits a laser beam alternately having at least two different energy values different from each other. The laser beam emitted from the light source 100 may have a square wave form.

The light source 100 may alternately perform ON/OFF operations. The light source 100 emits a laser beam during the ON operation and stops emitting the laser beam during the OFF operation. The output frequency of the laser beam may satisfy following Equation:

[Equation]

f>1000×v/d

where f is an output frequency (unit: e.g., kHz) of a laser beam emitted from the light source 100, v is a scanning velocity (unit: e.g., m/s) of the stage 400, and d is a step size (unit: e.g., μm).

The step size represents a distance between positions which the laser beam reaches on a donor substrate 300 in a scanning direction DR1 when a light source 100 performs two consecutive ON operations.

d may be less than about 5 μm. For example, when d is about 5 μm, v is about 0.1 m/s, and f may be greater than about 20 kHz. To obtain a more uniform pattern of the laser beam, d may be less than about 1 μm. For example, when d is about 1 μm, and v is about 0.1 m/s, f may be greater than about 100 kHz.

In a laser irradiation device according to an exemplary embodiment of the inventive concept, even when an LITI mask includes an opening having a dot shape, a laser beam emitted from a light source 100 may be controlled to have a square wave form. Thus, when the organic layer is formed, a sudden thermal expansion may be prevented from occurring in the donor substrate, thus preventing occurrence of cracks in the organic layer.

While the inventive concept has been shown and described with reference to exemplary embodiments thereof, it will be apparent to those of ordinary skill in the art that various changes in form and detail may be made thereto without departing from the spirit and scope of the inventive concept as defined by the following claims.

What is claimed is:

1. A laser induced thermal imaging (LITI) mask for forming an organic layer on a pixel area, the LITI mask comprising:
a transmissive part comprising a plurality of slits through which a laser beam passes, the transmissive part corresponding to the pixel area; and
a blocking part reflecting or blocking the laser beam.

2. The LITI mask of claim 1, wherein each of the slits extends in a direction substantially perpendicular to a scanning direction of the laser beam.

3. The LITI mask of claim 2, wherein the plurality of slits are spaced apart from each other in the scanning direction.

4. The LITI mask of claim 3, wherein a remaining portion of the transmissive part except for the plurality slits is formed of substantially the same material as the blocking part.

5. A laser irradiation device, comprising:
a light source emitting a laser beam at constant output energy;
a laser induced thermal imaging (LITI) mask disposed under the light source; and
a stage disposed under the LITI mask, wherein an accepter substrate having a pixel area is disposed on the stage, and
wherein the LITI mask comprises:
a transmissive part comprising a plurality of slits through which the laser beam passes, the transmissive part corresponding to the pixel area; and
a blocking part reflecting or blocking the laser beam.

6. The laser irradiation device of claim 5, wherein the stage moves in a scanning direction of the laser beam.

7. The laser irradiation device of claim 6, wherein the laser beam has a square wave form.

8. The laser irradiation device of claim 5, wherein each of the slits extends in a direction substantially perpendicular to a scanning direction of the laser beam.

9. The laser irradiation device of claim 8, wherein the plurality of slits are spaced apart from each other in the scanning direction.

10. A laser irradiation device, comprising:
a light source emitting a laser beam alternately having at least two energy values different from each other;
a laser induced thermal imaging (LITI) mask disposed under the light source; and
a stage disposed under the light source, wherein an accepter substrate having a pixel area is disposed on the stage, and
wherein the LITI mask comprises:
a transmissive part comprising an opening through which the laser beam passes, the opening having a dot shape, wherein the transmissive part corresponds to the pixel area; and
a blocking part reflecting or blocking the laser beam.

11. The laser irradiation device of claim 10, wherein the laser beam has a square wave form.

12. The laser irradiation device of claim 10, wherein an output frequency of the laser beam satisfies a following Equation:
[Equation]
f>1000×v/d
wherein f is the output frequency of the laser beam, v is a scanning velocity of the stage, and d is a step size.

13. The laser irradiation device of claim 12, wherein the step size is less than about 5 μm.

14. A laser irradiation device, comprising:
a light source emitting a laser beam;
a laser induced thermal imaging (LITI) mask disposed under the light source; and
a stage disposed under the LITI mask, wherein an accepter substrate having a pixel area is disposed on the stage, and
wherein the LITI mask comprises:
a transmissive part through which the laser beam passes, the transmissive part corresponding to the pixel area; and
a blocking part, wherein after passing through the transmissive part, the laser beam has a square wave form.

15. The laser irradiation device of claim 14, wherein the transmissive part includes a plurality of slits.

16. The laser irradiation device of claim 14, wherein the transmissive part includes an opening.

17. The laser irradiation device of claim 16, wherein the laser beam has at least two energy values that vary over time.

18. The laser irradiation device of claim 17, wherein the opening is rectangular in shape.
